(19) United States
(12) Patent Application Publication
(10) Pub. No.: US 2012/0221269 A1
(43) Pub. Date: Aug. 30, 2012

(54) METHOD AND SYSTEM FOR DETERMINING DC BUS LEAKAGE

(76) Inventors: Kent David Wanner, Fargo, ND (US); Perry Kim White, Indianapolis, IN (US)

(21) Appl. No.: 13/036,058

(22) Filed: Feb. 28, 2011

(51) Int. Cl. G06F 19/00; G01R 31/02

(52) U.S. Cl. 702/65; 324/551

(57) ABSTRACT

A method and system is provided for determining leakage resistances in a bus system. The bus system has a floating DC bus connected to bus voltage source. The system also includes a pair of known resistors, each connected to the bus by a switch. The method includes with the first switch closed and the second switch open, measuring a voltage Vprtp between the bus and the ground and measuring a voltage Vnrtp between the ground and the second terminal. The method also includes, with the first switch open and the second switch closed, measuring a voltage Vprtn between the bus and the ground and measuring a voltage

Vnrtn between the ground and the second terminal. The first and second leakage resistances are then calculated as a function of the known resistors and the measured voltages.

### FIELD OF THE INVENTION

The present disclosure relates to a method of determining leakage resistances in an electrical bus system.

### BACKGROUND OF THE INVENTION

It is known to provide a mobile vehicle with a floating, ungrounded high voltage DC bus system. It is desirable to monitoring such a DC bus system for insulation integrity (resistance and ideally capacitance) to make sure the entire high voltage system is correctly installed and maintained. Some components typically involved in this high voltage system could be inverters, generator(s), motor(s), brake resistor, DC/DC converters, batteries, and all high voltage cabling. A known technique is described in published US Application No. 20090323233 published 31 Dec. 2009 and assigned to the assignee of the present application. This known technique involves injecting a signal (longitudinally) into both sides of the isolated DC bus relative to the chassis common reference and sensing the current that flows from the bus to the chassis reference. The leakage resistance is proportional to the measured current. One confounding aspect of this approach arises from the imbalance in the leakage resistance to chassis from either side of the DC bus. The (offset) current that flows as a result of the imbalance can be substantially larger than the (signal) current being used to assess the leakage resistance. This situation requires the sensing circuit to accommodate the wide range of the: offset just to measure the smaller signal current. Concurrently, the “signals” of interest are very small due to small (30V) excitation voltages and large resistive division (Rm/(Rm+Rtap/2) about 1/200). This creates a very difficult signal to noise ratio problem in the electrically noisy environments of electric drive vehicles (high voltage and high current switching in intverters, motors, etc.). Existing products, such as those manufactured by Bender, also take a long time to take a measurement and cannot measure leakage capacitance between the chassis and the high voltage DC bus. The existing solutions are also very costly and add to the problem of cost effectiveness in implementing an electric drive on a vehicle.

### SUMMARY

According to aspects of the present disclosure, a bus system has a floating DC bus connected to bus voltage source. The bus voltage source has a first terminal connected to the bus and has a second terminal. A first known resistor is connected between the bus and a ground, and a first switch is connected between the bus and the first resistor. A second known resistor is connected between the ground and the second terminal, and a second switch connected between the second terminal and the second resistor. An aspect of the invention is a method of determining a first leakage resistance between the bus and the ground and determining a second leakage resistance between the second terminal and the ground. The method includes with the first switch closed and the second switch open, measuring a voltage Vprtp between the bus and the ground and measuring a voltage Vnrtp between the ground and the second terminal. The method also includes, with the first switch open and the second switch closed, measuring a voltage Vprtn between the bus and the ground and measuring a voltage Vnrtn between the ground and the second terminal. The first and second leakage resistances are calculated as a function of the known resistors and the measured voltages.

This system and method has the primary advantage of being able to determine not only the DC leakage, but the DC leakage from each polarity of the high voltage bus. It is possible to implement this system in such a way as to obtain better quality “signals” resulting in more accurate results than previous methods. It is also possible to obtain faster results due to reduced time constants in the test networks. It likewise has the ability to detect faults on motor or generator phases when inverter switches are closed. This can be done as a startup diagnostic, during operation, or in a special diagnostic mode to help determine the exact location of the fault. The method can perform at low or high voltage. This circuit can be incorporated into an inverter or as a standalone module. All of these features make this system much more valuable in detecting and diagnosing various types, magnitudes, and locations of faults effectively without the need for well-trained service personnel, high voltage measurements, or expensive diagnostic meters/tools.

### BRIEF DESCRIPTION OF THE DRAWINGS

FIG. 1 is a schematic circuit diagram of a vehicle DC electrical bus system according to the present invention;

FIG. 2 is a flow chart illustrating an embodiment of the present invention; and

FIG. 3 is a flow chart illustrating an alternate embodiment of the present invention; and

FIG. 4 is a schematic circuit diagram of a vehicle DC electrical bus system according to an alternate embodiment of the present invention.

### DETAILED DESCRIPTION OF THE DRAWINGS

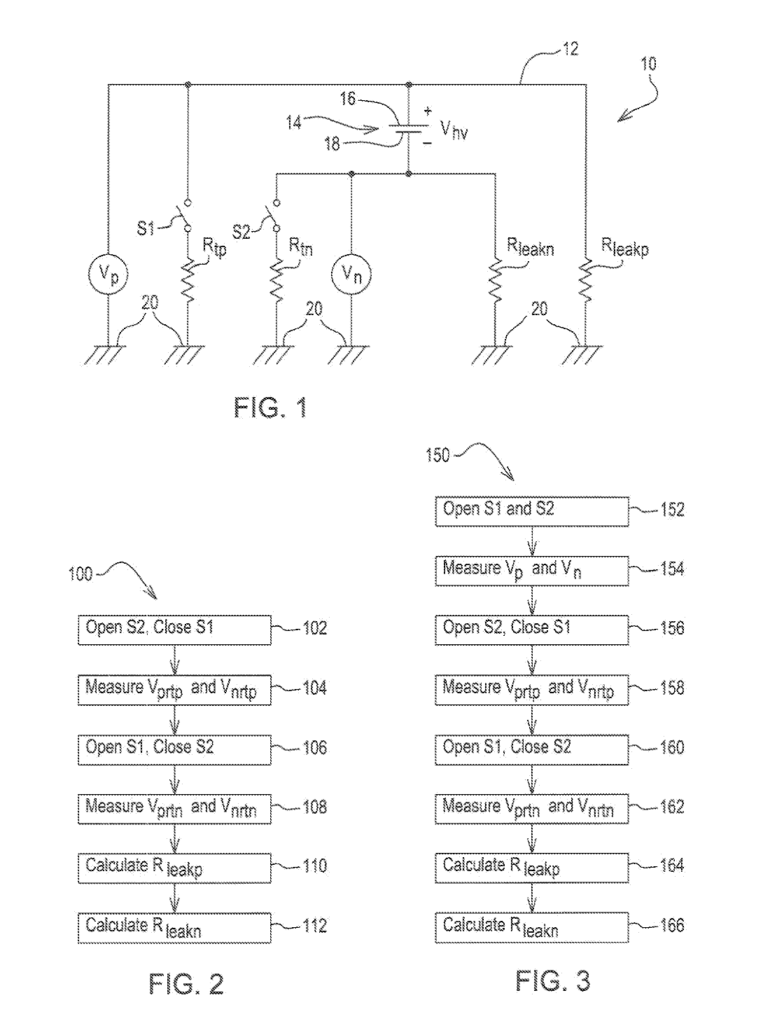

Referring to FIG. 1, a DC bus system 10 includes a DC bus 12, a source 14 of high voltage Vbus, such as a generator or battery, which provides a high DC voltage, such as 700 to 800 volts DC. Source 14 has a positive or high side terminal 16 connected to the bus 12. A first known resistor Rtp is connected between the bus 12 and a ground potential 20 such as a chassis (not shown) of the vehicle. (not shown), and a first switch S1 is connected between the bus 12 and the first resistor Rtp. A second known resistor Rtn is connected between the ground 20 and the negative or low side terminal 18 of the source 14, and a second switch S2 is connected between the low voltage terminal 18 and the second resistor Rtn. The high DC voltage may be in the range of 700 to 800 volts DC, but other the present invention is applicable to other voltage ranges as well. For this voltage range resistors Rtp and Rtn may be on the order of 200 K ohms, but other resistances could be used, depending on what DC bus voltage is used. Rleakp represents a first unknown leakage resistance between the bus 12 or the positive side of the source 14 and the ground 20. Rleakn represents a second unknown leakage resistance between the low side terminal 18 and the ground 20.

Referring now to FIG. 2, the following is a description of a method 100 of determining Rleakp and Rleakn.

First, with the first switch S1 closed and the second switch S2 open in step 102, then in step 104, measuring a voltage Vprtp between the bus 12 and the ground 20 and measuring a voltage Vnrtp between the ground 20 and the negative terminal 18. As a practical matter, the Vn side voltages need not be measured directly. Instead these voltages (Vn, Vnrtp, and Vnrtn) are, preferably derived by subtracting the corresponding high side voltage measurement from the known bus voltage Vbus, assuming that the bus voltage is relatively stable during the measurement operations.

Next, with the first switch S1 open and the second switch S2 closed by step 106, then in step 108, measuring a voltage Vprtn between the bus and the ground potential and measuring a voltage Vnrtn between the ground potential and the low voltage terminal;

Next, in step 110 the first leakage resistance Rleakp is calculated according to the following equation:

Rleakp=Rtp×Rtn×[(Vprt/−Vnrt)−(Vprt/−Vnrt)]×(−Vnrt/Vprt)×[1/(Rtp×(−Vnrt/Vprt)+Rtn)].

Next, in step 112 the second leakage resistance Rleakn is calculated according to the following equation:

Rleakn=Rtp×Rtn×[(Vprt/−Vnrt)−(Vprt/−Vnrt)]×(−Vnrt/Vprt)×[1/(Rtp+Rtn×(Vprt/−Vnrt))].

The above method uses only measurements taken during the sequential application of the known leakage resistors and uses mathematical relationships for those measured voltages. This speeds up the data collection process, resulting in faster operation.

Referring now to FIG. 3, the following is a description of an alternative method 150 of determining Rleakp and Rleakn.

First, with the first and second switches open by step 152, then in step 154, measuring a voltage Vp between the bus 12 and the ground 20 and measuring a voltage Vn between the ground 20 and the negative terminal 18.

Next, with the first switch S1 closed and the second switch S2 open by step 156, then in step 158, measuring a voltage Vprtp between the bus 12 and the ground 20 and measuring a voltage Vnrtp between the ground 20 and the negative terminal 18.

Next, with the first switch S1 open and second switch S2 closed by step 160, then in step 162, measuring a voltage Vprtn between the bus 12 and the ground 20 and measuring a voltage Vnrtn between the ground 20 and the negative terminal 18.

Next, in step 164, the first leakage resistance Rleakp is calculated according to the following equation [1]:

Rleakp=Rtp×(((Vp/−Vn)/(Vprtp/−Vnrtp))−1);

and

Next, in step 166, the second leakage resistance Rleakn is calculated according to the following equation [2]:

Rleakn=Rtn×(((Vprtn/−Vnrtn)/(Vp/−Vn)) −1).

Alternatively, the second leakage resistance. Rleakn is calculated according to the following equation [3]:

Rleakn=Rleakp×(−Vn/Vp).

Alternatively, if the second leakage resistance Rleakn is first calculated according equation [2], then the first leakage resistance Rleakp can be calculated according to the following equation [4]:

Rleakp=Rleakn×(Vp/−Vn).

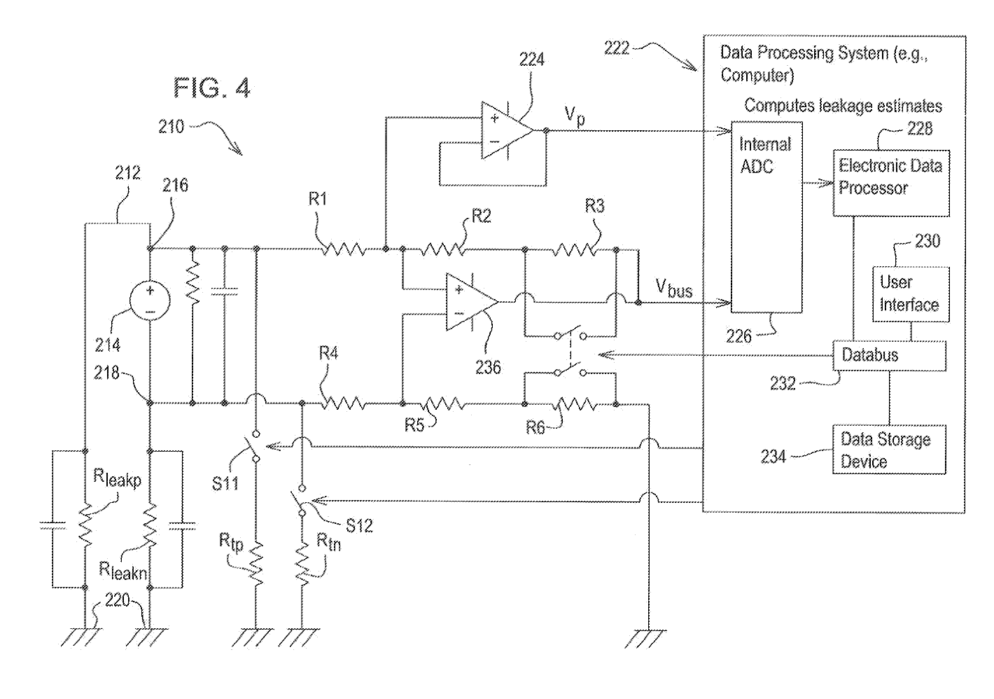

Referring now to FIG. 4, an alternate a DC bus system 210 includes a DC bus 212, a source 214 of high voltage Vbus, such as a generator or battery, which provides a high DC voltage, such as 700 to 800 volts DC. Source 214 has a positive or high side terminal 216 connected to the bus 212 and a negative or low side, terminal 218 connected to the vehicle chassis or ground 220. Rleakp represents a first unknown leakage resistance between the bus 212 or the high side of the source 214 and the ground 220. Rleakn represents a second unknown leakage resistance between the low side terminal 218 and the ground 220.

Terminal 216 is connected to a bus voltage input of a central process unit CPU 222 via series connected known resisters R1, R2 and R3. A differential amplifier 224 has an input connected between resistors R1 and R2, and an output connected to a measured voltage Vp input of CPU 222. CPU 222 includes known convention components such as an internal analog to digital converter ADC 226, an electronic data processor 228, a data bus 230, a user interface 232 and a data storage device 234.

Terminal 218 is connected to ground 220 via series connected known resisters R4, R5 and R6. An op amp 236 includes-a first input connected between resistors R1 and R2, a second input connected between resistors R4 and R5 and an output connected to the Vp input of CPU 222. A first gain switch GS1 is connected in parallel with known resistor R3. A second gain switch GS2 is connected in parallel with known resistor R6. Switches S11 and S12 are preferably ganged so that they close and open together, and short circuit resistors R3 and R6 together. The gain switches may be used to improve resolution at low bus voltages, such as 20V, obtained by changing the gain and allows the embodiment to work well over a large range of bus voltages, but this is not part of the present invention.

A first known resistor Rtp is connected between the bus 212 and ground 220 such as a chassis (not shown) of the vehicle (not shown), and a first switch S11 is connected between the bus 212 and the first resistor Rtp. A second known resistor Rtn is connected between the ground 220 and the negative or low side terminal 218 of the source 214, and a second switch S12 is connected between the low voltage terminal 218 and the second resistor Rtn. With this system the high DC voltage may be in a wide range, such as from 20 to 700 to 800 volts DC. For a 700 to 800 voltage range resistors Rtp and Rtn may be on the order of 200 K ohms, but other resistances could be used, depending on what DC bus voltage is used. The amplifiers 224 and 236 scale the voltages for the ADC 226. The ADC 226 samples and converts the scaled voltages to digital representations of the measured voltages. Then the CPU 222 controls the switches S11 and S12 and executes the algorithm or method 100 steps previously described.

With the system shown in FIG. 4, the high side bus voltage Vp is measured directly and the bus voltage Vbus is measured directly. The low side voltage Vn is not measured directly, but is derived by the CPU 222 using the relationship Vn=Vp−Vbus. In this manner all the needed low side voltages Vn, Vnrtp, and Vnrtn can all be derived from a relationship to the bus voltage Vbus.

In addition, it would also be possible to generate two equations and solve for the two leakage resistances by taking two voltage measurements a) with both switches open and with only the first switch closed, or b) with both switches open and with only the second switch closed. Alternatively, yet another approach would be to close both switches S1 and S2 to get the second equation allowing solution.

This might provide better accuracy may be better in some cases than the “only one switch” approach, depending on the unknown leakage.

It may be possible to further improve results by measuring the unperturbed bus voltage between alternate switch closures. This would perhaps enhance accuracy if the bus voltage were to be varying more than an acceptable amount (thereby introducing errors into the measurements).

Thus, the above method detects the voltages appearing on each polarity of the high voltage bus with respect to the chassis. In this method, each polarity voltage is determined both before and during the application of a known leakage path. The known leakage is applied to each side of the high voltage bus in turn. The unknown leakage paths are determined with mathematical relationships between the known temporary leakages and the observed voltages. The above methods could be enhanced by taking multiple measurements and averaging the results to obtain more accurate and stable results.

The above methods make possible variable leakage determination times. This may allow fast determination (such as less than 1 second) of low resistance conditions while also adapting for more accuracy with a longer time (on the order of 15 seconds). The methods could be modified to use the voltage measurements to determine the time constant of induced measurement transients. Combining the time constant with the computed resistive leakages would allow assessment of the leakage capacitance. Capacitance assessment could allow automatic optimization of the leakage assessment time for best accuracy given the time constants associated with the leakage paths, although substantially higher computational demands would result. Still a further concept would assess the quality (noise content, transient characteristics, etc.) of the measurement data to provide a “confidence” metric with the resulting computations. All of this is achievable from two voltage measurements and two “perturbing” or excitation leakage paths.

A system performing these methods could include a built-in self test feature which, “on command”, puts a known resistive fault between the DC bus and the chassis of the vehicle, and the ability to survive hi-pot testing from high voltage to chassis while in the circuit.

While the disclosure has been illustrated and described in detail in the drawings and foregoing description, such illustration and description is to be considered as exemplary and not restrictive in character, it being understood that illustrative embodiments have been shown and described and that all changes and modifications that come within the spirit of the disclosure are desired to be protected. It will be noted that alternative embodiments of the present disclosure may not include all of the features described yet still benefit from at least some of the advantages of such features. Those of ordinary skill in the art may readily devise their own implementations that incorporate one or more of the features of the present disclosure and fall within the spirit and scope of the present invention as defined by the appended claims.

We claim:

1. In a bus system having a floating DC bus connected to bus voltage source, the bus voltage source having a first terminal connected to the bus and having a second terminal, a first resistor Rtp connected between the bus and a ground, a first switch connected between the bus and the first resistor, a second resistor Rtn connected between the ground and the second terminal, and a second switch connected between the second terminal and the second resistor, a method of determining a first leakage resistance Rleakp between the bus and the ground and determining a second leakage resistance Rleakn between the second terminal and the ground, the method comprising:
a. with the first switch closed and the second switch open, measuring a voltage Vprtp between the bus and the ground and measuring a voltage Vnrtp between the ground and the second terminal;
b. with the first switch open and the second switch closed, measuring a voltage Vprtn between the bus and the ground and measuring a voltage Vnrtn between the ground and the second terminal;
c. calculating the first leakage resistance Rleakp and the second leakage resistance Rleakn as a function of Rtp, Rtn, Vprtn, Vnrtn, Vprtp and Vnrtp.

2. In a bus system having a floating DC bus connected to bus voltage source, the bus voltage source having a first terminal connected to the bus and having a second terminal, a first resistor Rtp connected between the bus and a ground, a first switch connected between the bus and the first resistor, a second resistor Rtn connected between the ground and the second terminal, and a second switch connected between the second terminal and the second resistor, a method of determining a first leakage resistance Rleakp between the bus and the ground and determining a second leakage resistance Rleakn between the second terminal and the ground, the method comprising:
a. with the first switch closed and the second switch open, measuring a voltage Vprtp between the bus and the ground and measuring a voltage Vnrtp between the ground and the second terminal;
b. with the first switch open and the second switch closed, measuring a voltage Vprtn between the bus and the ground and measuring a voltage Vnrtn between the ground and the second terminal;
c. calculating the first leakage resistance Rleakp equal to Rtp×Rtn×[(Vprtn/V−Vnrtn)−(Vprtp/−Vnrtp)]×(V−Vnrtp/Vprtp)×[1/(Rtp×(V−Vnrtp/Vprtp)+Rtn)]; and
d. calculating the second leakage resistance Rleakn equal to Rtp×Rtn×[(Vprtn/−Vnrtn)−(Vprtp/−Vnrtp)]×(−Vnrtp/Vprtp)×[1/(Rtp+Rtn×(Vprtn/−Vnrtn))].

3. In a bus system having a floating DC bus connected to bus voltage source, the bus voltage source having a first terminal connected to the bus and having a second terminal, a first resistor Rtp connected between the bus and a ground, a first switch connected between the bus and the first resistor, a second resistor Rtn connected between the ground and the second terminal, and a second switch connected between the second terminal and the second resistor, a method of determining a first leakage resistance Rleakp between the bus and the ground and determining a second leakage resistance Rleakn between the second terminal and the ground, the method comprising:
a. with the first and second switches open, measuring a voltage Vp between the bus and the ground and measuring a voltage Vn between the ground and the second terminal;
b. with the first switch closed and the second switch open, measuring a voltage Vprtp between the bus and the ground and measuring a voltage Vnrtp between the ground and the second terminal;
c. with the first switch open and the second switch closed, measuring a voltage Vprtn between the bus and the ground and measuring a voltage Vnrtn between the ground and the second terminal;
d. calculating the first leakage resistance Rleakp as a function of Rtp, Vp, Vn, Vprtp and Vnrtp; and
e. calculating the second leakage resistance Rleakn as a function of Rtn, Vprtn, Vnrtn, Vp and Vn.

4. In a bus system having a floating DC bus connected to bus voltage source, the bus voltage source having a first terminal connected to the bus and having a second terminal, a first resistor Rtp connected between the bus and a ground, a first switch connected between the bus and the first resistor, a second resistor Rtn connected between the ground and the second terminal, and a second switch connected between the second terminal and the second resistor, a method of determining a first leakage resistance Rleakp between the bus and the ground and determining a second leakage resistance Rleakn between the second terminal and the ground, the method comprising:
a. with the first and second switches open, measuring a voltage Vp between the bus and the ground and measuring a voltage Vn between the ground and the second terminal;
b. with the first switch closed and the second switch open, measuring a voltage Vprtp between the bus and the ground and measuring a voltage Vnrtp between the ground and the second terminal;
c. with the first switch open and the second switch closed, measuring a voltage Vprtn between the bus and the ground and measuring a voltage Vnrtn between the ground and the second terminal;
d. calculating the first leakage resistance Rleakp equal to Rtp×(((Vp/−Vn)/(Vprtp/−Vnrtp)) −1); and
e. calculating the second leakage resistance Rleakn equal to Rtn×(((Vprtn/−Vnrtn)/(Vp/−Vn)) −1), or equal to Rleakp×(−Vn/Vp).

5. In a bus system having a floating DC bus connected to bus voltage source, the bus voltage source having a first terminal connected to the bus and having a second terminal, a first resistor Rtp connected between the bus and a ground, a first switch connected between the bus and the first resistor, a second resistor Rtn connected between the ground and the second terminal, and a second switch connected between the second terminal and the second resistor, a method of determining a first leakage resistance Rleakp between the bus and the ground and determining a second leakage resistance Rleakn between the second terminal and the ground, the method comprising:
a. with the first and second switches open, measuring a voltage Vp between the bus and the ground and measuring a voltage Vn between the ground and the second terminal;
b. with the first switch closed and the second switch open, measuring a voltage Vprtp between the bus and the ground and measuring a voltage Vnrtp between the ground and the second terminal;
c. with the first switch open and the second switch closed, measuring a voltage Vprtn between the bus and the ground, and measuring a voltage Vnrtn between the ground and the second terminal;
d. calculating the second leakage resistance Rleakn equal to:
Rtn×(((Vprtn/−Vnrtn)/(Vp/−Vn)) −1); and
e. calculating the first leakage resistance Rleakp equal to:
Rtp×(((Vp/−Vn)/(Vprtp/−Vnrtp)) −1), or equal to Rleakn×(Vp/−Vn).

6. A bus system comprising:
a floating DC bus connected to a bus voltage source, the bus voltage source having a first terminal connected to the bus and having a second terminal, the bus system having an unknown first leakage resistance Rleakp between the first terminal and ground and an unknown second leakage resistance Rleakn between the second terminal and ground;
a first known resistor Rtp connected between the bus and ground;
a first switch connected between the bus and the first resistor;
a second known resistor Rtn connected between ground and the second terminal;
a second switch connected between the second terminal and the second resistor; and
a central processing unit connected to the bus, the central processing unit with the first switch closed and the second switch open, determining a voltage Vprtp between the bus and ground and determining a voltage Vnrtp between ground and the second terminal, the central processing unit with the first switch open and the second switch closed, determining a voltage Vprtn between the bus and ground and determining a voltage Vnrtn between ground and the second terminal, and the central processing unit calculating the first leakage resistance Rleakp and the second leakage resistance Rleakn as a function of Rtp, Rtn, Vprtn, Vnrtn, Vprtp and Vnrtp.

7. The bus system of claim 6, wherein:
the central processing unit calculates the first leakage resistance Rleakp equal to Rtp×Rtn×[(Vprtn/−Vnrtn)−(Vprtp/−Vnrtp)]×(−Vnrtp/Vprtp)×[1/(Rtp×(−Vnrtp/Vprtp)+Rtn)], and calculates the second leakage resistance Rleakn equal to Rtp×Rtn×[(Vprtn/−Vnrtn)−(Vprtp/−Vnrtp)]×(−Vnrtp/Vprtp)×[1/(Rtp+Rtn ×(Vprtn/−Vnrtn))].
